(19) United States
(12) Patent Application Publication
(10) Pub. No.: US 2014/0360550 A1
(43) Pub. Date: Dec. 11, 2014

(54) NANOCRYSTAL COATED FLEXIBLE SUBSTRATES WITH IMPROVED THERMOELECTRIC EFFICIENCY

(71) Applicants: Yue Wu, West Lafayette, IN (US); Daxin Liang, Jilin (CN); Haoran Yang, West Lafayette, IN (US); Scott Finefrock, West Lafayette, IN (US)

(72) Inventors: Yue Wu, West Lafayette, IN (US); Daxin Liang, Jilin (CN); Haoran Yang, West Lafayette, IN (US); Scott Finefrock, West Lafayette, IN (US)

(73) Assignee: PURDUE RESEARCH FOUNDATION, West Lafayette, IN (US)

(21) Appl. No.: 14/238,323

(22) PCT Filed: Aug. 11, 2012
(86) PCT No.: PCT/US2012/050485

§ 371 Date: Apr. 25, 2014

Related U.S. Application Data
(60) Provisional application No. 61/522,680, filed on Aug. 11, 2011.

(51) Int. Cl. H01L 35/16; H01L 35/34; H01L 35/32

(52) U.S. Cl. CPC H01L 35/16; H01L 35/32; H01L 35/34
USPC 136/230; 438/54; 136/201

(57) ABSTRACT

This disclosure examines using lead telluride nanocrystals as well as other materials suitable for thermoelectric conversion, particularly materials with high Figure of Merit values, as coatings on flexible substrates.

### CROSS REFERENCE TO RELATED APPLICATION

This application claims the benefit of U.S. Provisional Application No. 61/522,680, filed Aug. 11, 2011, the disclosure of which is expressly incorporated by reference.

### FIELD

This disclosure generally relates to material suitable for thermoelectric conversion and particularly to materials with high Figure of Merit.

### BACKGROUND

During the last hundreds of years, fossil fuels (including coal, petroleum, and natural gas) have been used as a main source of energy. Examples of energy conversion include operating power plants which may burn coal to produce electricity operating internal combustion engines which burn petroleum to produce motion, lighting incandescent light bulbs which may burn natural gas to give off light, etc. Production of thermal energy is a byproduct of each of these forms of energy conversion. Production of thermal energy is a byproduct in almost every energy converting activity. Currently, most of the produced thermal energy is lost, as is thereby considered wasted. It would be beneficial to reclaim some or most of the thermal energy and convert it to a useful form of energy.

Thermoelectric (TE) devices provide one way to convert thermal energy into electrical energy. A thermoelectric device positioned between a hot reservoir and a cold reservoir can convert the thermal difference between these reservoirs into an electrical current. Referring to FIG. 5, a schematic of an application of prior art use of thermoelectric material is depicted.

The mechanism by which thermal energy is converted to electrical current is commonly measured by the Seebeck effect. The Seebeck effect can be explained as follows. A thermal gradient at a junction of two dissimilar materials, ΔT=T_{H}−T_{C} (see FIG. 4), can generate a voltage ΔV. The relationship between the thermal gradient ant the voltage is known as the Seebeck effect. The generated voltage is governed by Formula 1:

$$S = \frac{Δ V}{Δ T}$$

where S is Seebeck coefficient,
ΔV is the generated voltage; and
AT is the thermal gradient. In application, the higher the Seebeck coefficient the higher voltage ΔV generated for the same thermal gradient ΔT. Whether the Seebeck coefficient is a positive or negative number depends on whether electrical charge carriers are holes or electrons.

Figure of Merit is one way to measure the efficiency of the thermoelectric material and structure. Figure of Merit is may be denoted as ZT and as denoted may be expressed as Formula 2:

$$ZT = \frac{{S}^{2} σ}{κ} T$$

where S is the Seebeck coefficient,
σ is the electrical conductivity,
κ is thermal conductivity, and
T is the temperature.

As apparent from Formula 2, to achieve a high figure of merit, the thermoelectric material requires a low thermal conductivity and a high electrical conductivity. Low thermal conductivity slows heat transfer from the hot body to the cold body. The high electrical conductivity lowers electrical losses due to electrical resistance. For bulk materials, an increase in S usually results in a decrease in σ. A decrease in the electrical conductivity leads to a decrease in the therrnal conductivity as indicated by the Wiedemann-Franz law. Application of the Wiedemann-Franz law produces a barrier for the practical applications of thermoelectric (TE) materials.

Great efforts have been made to incorporate nanostructure materials into thermoelectric applications because of enhancement to Figure of Merit (ZT) due to quantum confinement. When the dimensions of material are reduced to nanometer scale, quantum confinement is introduced, altering the electronic structure. In quantum confinement, the number of available energy states is reduced causing a larger occupancy of the remaining states and a greater difference in energy between states. Sharp peaks in the electronic density of states may cause high power factor and thus an increased Figure of Merit (ZT). Reduced dimensions of material can also increase phonon scattering by introduction of interfaces and surfaces, which can reduce thermal conductivity, resulting in improvement of ZT.

Different materials have been investigated to improve the Figure of Merit. Bismuth telluride (Bi₂Te₃), and lead telluride (PbTe) are examples of thermoelectric materials being investigated. Lead (II) telluride (also known as the naturally occurring mineral altaite) has attracted much interest due to its excellent thermoelectric properties including a low level of thermal conductivity. However, practical applications of thermoelectric materials have not been realized because most of the materials are rigid and cannot be made into desirable shapes.

Therefore, it is desirable to find a straightforward and scalable way to make flexible thermoelectric materials with very low thermal conductivity and high Figure of Merit (Z7) values that can be easily made into different shapes to make efficient flexible, wearable or even portable thermoelectric devices for purposes of energy conversion.

### SUMMARY

The present disclosure includes a thermoelectric structure, comprising, a flexible substrate, and nanocrystals coated over the flexible substrate.

The present disclosure also includes a method of coating lead telluride nanocrystals on a flexible substrate, the method comprising the steps of synthesizing lead telluride nanocrystals in solution, comprising the steps of, degassing and drying a first solution of lead oxide, oleic acid and 1-octodecene at 140° C. for at least approximately one hour under an inert atmosphere, contacting the first solution with a second solution of tri-n-octylphosphine and tellurium, wherein the second solution is prepared in a glovebox, quenching the reaction by immersing the mixture in a water bath, and contacting the reaction mixture with hexane; coating lead telluride nanocrystals on a flexible substrate, comprising the steps of, contacting flexible substrate to lead telluride nanocrystals, drying nanocrystal coated flexible substrate, contacting nanocrystal coated flexible substrate with hydrazine aqueous solution, contacting nanocrystal coated flexible substrate with acetonitrile; and repeating each coating step until nanocrystals form a uniform film on nanocrystal coated flexible substrate, and annealing nanocrystal coated flexible substrate to form a uniform layer of nanocrystal on flexible substrate.

### BRIEF DESCRIPTION OF THE DRAWINGS

The above-mentioned and other features of this disclosure, and the manner of attaining them, will become more apparent and the disclosure itself will be better understood by reference to the following description of embodiments of the disclosure taken in conjunction with the accompanying drawings, wherein:

FIG. 1a depicts a schematic used for a coating procedure of bare glass fibers and lead telluride (PbTe) coated glass fibers.

FIG. 1aa depicts an image of bare glass fibers.

FIG. 1ab depicts an image of lead telluride (PbTe) coated glass fibers.

FIG. 1b depicts scanning electron microscopy image of PbTe nanocrystals coated glass fibers.

FIG. 1bb depicts scanning electron microscopy image of PbTe nanocrystals coated glass fibers.

FIG. 1c depicts transmission electron microscopy image of PbTe nanocrystals after annealing.

FIG. 2a depicts X-Ray Diffraction (XRD) patterns of PbTe nanocrystals for 1) before annealing, and 2) after annealing.

FIG. 2b depicts transmission electron microscopy images of PbTe nanocrystals with an average diameter of about 13±3 nm.

FIG. 2bb insert depicts particle size distribution.

FIG. 2c depicts high-resolution transmission electron microscopy images of a PbTe nanocrystal.

FIG. 3a depicts a graph of electrical conductivity for PbTe nanocrystals on a flexible substrate according to an embodiment of the present disclosure. The graph illustrates electrical conductivity measured in siemens per meter, vs. temperature, measured in Kelvin (K).

FIG. 3b depicts a graph of Seebeck coefficient for PbTe nanocrystals on a flexible substrate according to an embodiment of the present disclosure. The graph illustrates Seebeck coefficient measured in microvolts per K, vs. temperature, measured in K.

FIG. 3c depicts a graph of power factor for PbTe nanocrystals on a flexible substrate according to an embodiment of the present disclosure. The graph illustrates power factor measured in miliwatts per meter per K, vs. temperature, measured in K.

FIG. 3d depicts a graph of thermal conductivity for PbTe nanocrystals on a flexible substrate according to an embodiment of the present disclosure. The graph illustrates thermal conductivity measured in watts per meter and K, vs. temperature, measured in K.

FIG. 3e depicts a graph of Figure of Merit (ZT) for PbTe nanocrystals on a flexible substrate according to an embodiment of the present disclosure. The graph illustrates Figure of Merit (ZT) vs. temperature, measured in K.

FIG. 3f depicts a histogram of highest ZT values obtained from different measurements.

FIG. 4a depicts a picture of a measurement device with bended fibers according to an embodiment of the present disclosure, showing flexibility of the fibers and the bending angle of 84.5° .

FIG. 4b depicts a graph of the electrical conductivity for PbTe nanocrystals coated on the bent fibers of FIG. 4a. The graph illustrates electrical conductivity measured in siemens per meter, vs. temperature, measured in K.

FIG. 4c depicts a graph of Seebeck coefficient for PbTe nanocrystals coated on the bent fibers of FIG. 4a. The graph illustrates Seebeck coefficient measured in microvolts per K, vs. temperature, measured in K.

FIG. 4d depicts a graph of comparison of Figure of Merit (ZT) and power factor, measured in miliwatts per meter per K vs. temperature obtained from flat and bent PbTe nanocrystal coated glass fibers.

FIG. 4da depicts the graph of FIG. 4d comparison of ZT vs. temperature obtained from flat and bent PbTe nanocrystal coated glass fibers.

FIG. 4db depicts the graph of FIG. 4d comparison of power factor, measured in miliwatts per meter per K vs. temperature obtained from flat and bent PbTe nanocrystal coated glass fibers.

FIG. 5 is a schematic of an application of prior art use of thermoelectric material.

Corresponding reference characters indicate corresponding parts throughout the several views. Although the drawings represent embodiments of the present disclosure, the drawings are not necessarily to scale and certain features may be exaggerated in order to better illustrate and explain the present disclosure.

### DETAILED DESCRIPTION OF THE EXEMPLARY EMBODIMENTS

The embodiments disclosed below are not intended to be exhaustive or limit the disclosure to the precise forms disclosed in the following detailed description. Rather, the embodiments are chosen and described so that others skilled in the art may utilize their teachings.

### Experimental

### Preparation of Lead (II) Tellurium Nanocrystals

Tri-n-octylphosphine (TOP, 97%), 1-Octadecene (ODE, 90%), Oleic acid (OA, 90%), Lead (II) oxide (PbO, 99.9+%), Tellurium powder (99.8%), Hexane (98.5%), Acetone (99.5%), Hydrazine (98%) and Acetonitrile (99.8%) were used for synthesis of lead telluride (PbTe) nanocrystals under nitrogen (N₂) using a Schlenk line.

PbTe nanocrystals were synthesized according to an exemplary process, as follows. 0.223 g PbO, 0.7 g OA and 5 g ODE are degassed and dried at 140° C. for at least 1 hour in a 50 mL round-bottom flask under N₂. A TOP-Te solution is prepared in a glovebox with a concentration of approximately 0.75M and diluted to approximately 0.5M by ODE. 3 mL of 0.5M TOP-Te solution is then injected and reacted at 250° C. for 1 min. The reaction is then quenched by immersing the flask in a water bath. Once the temperature reached 70° C., 5 mL of hexane is injected and the flask is allowed to cool down to ambient temperature.

After cooling to room temperature, the reaction is then washed with a 1:1 volume ratio hexane/acetone pair for 3 times to remove any impurity.

Similar PbTe nanocrystal synthesis techniques have been reported several times previously. Others synthesize PbTe nanocrystals using similar procedures with slight adjustments. For example: i) squalane, diphenyl ether, or TOP can replace ODE as the reaction solvent, ii) lead acetate trihydrate can replace lead oxide, iii) ethanol can replace acetone as the precipitating agent during nanocrystal washing, iv) the reaction time and temperature can be varied significantly to achieve different nanocrystal sizes.

It is envisioned that several conditions can be modified within the scope of this present disclosure. For example, the concentration of washed PbTe nanocrystals dissolved in hexane or chloroform can be adjusted by simply adding acetone, centrifuging, pouring out the liquid supernatant, and adding a specific amount of solvent, such as chloroform or hexane. Therefore, if a large concentration is desired, washed nanocrystals could be dissolved in a very small amount of solvent.

### EXAMPLE 1

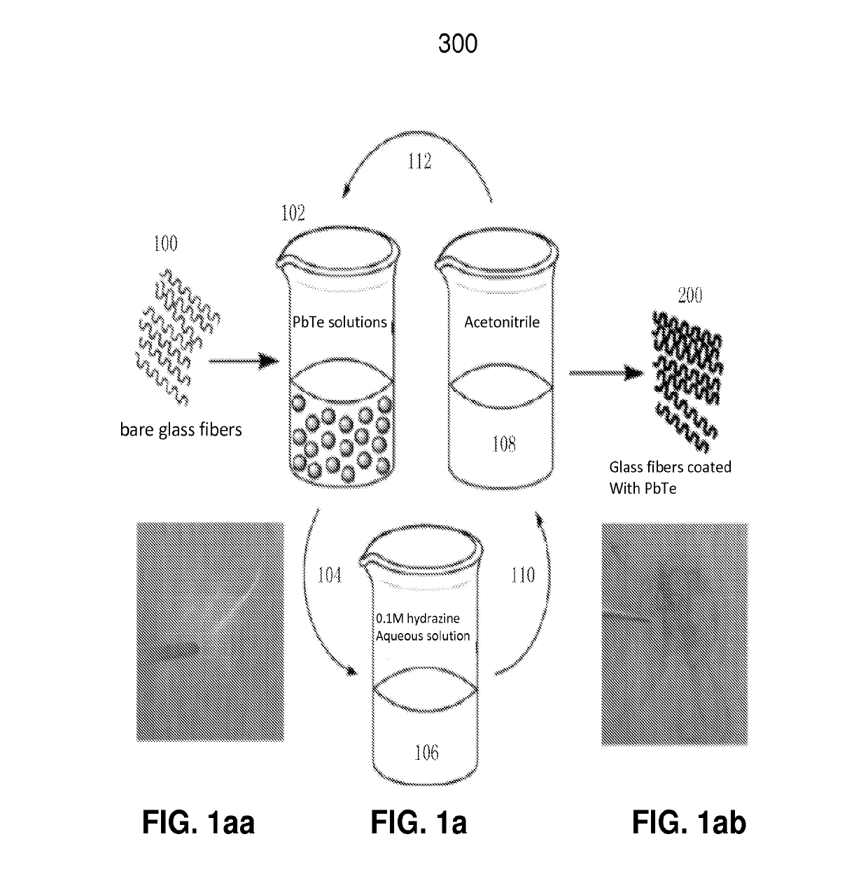

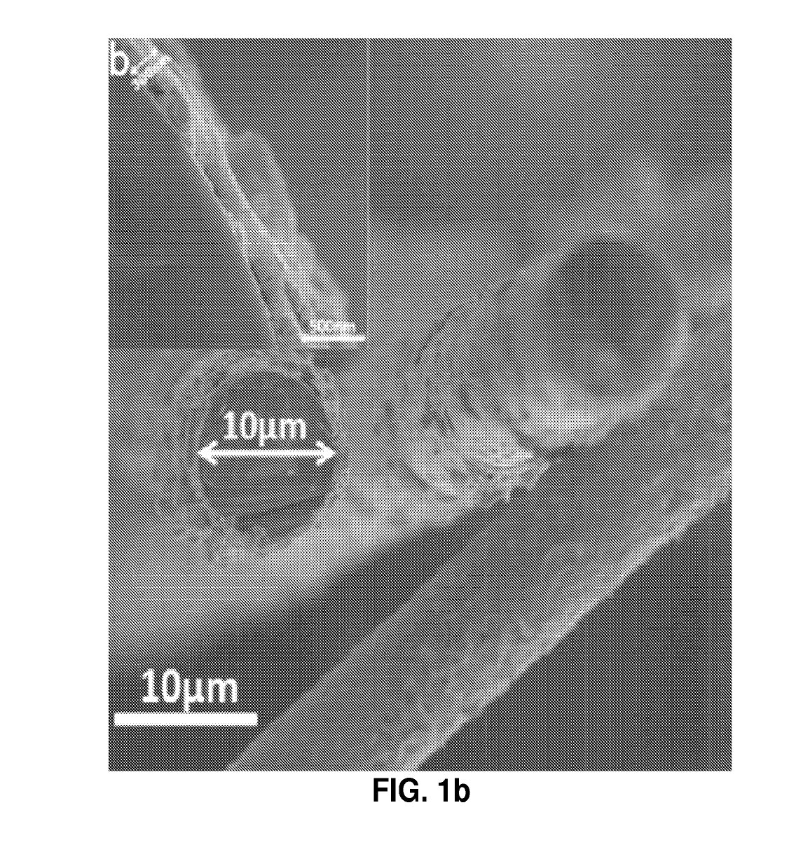

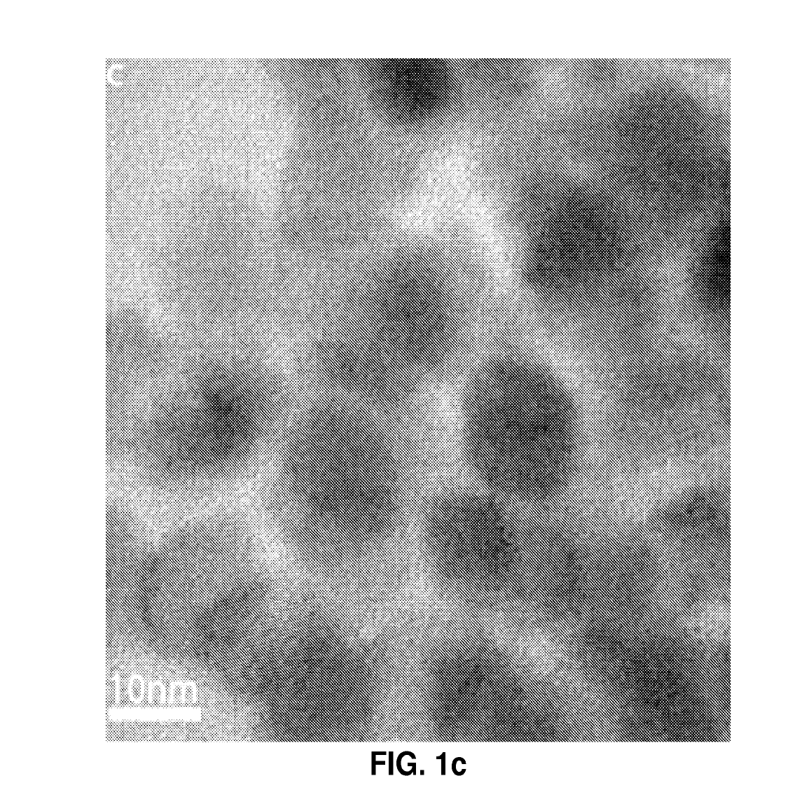

FIG. 1a depicts a schematic used for a coating procedure of flexible substrates 100, such as bare glass fibers 100, to create lead telluride (PbTe) coated glass fibers 200. As shown in FIG. 1a, procedure of coating 300 is as follows:

1) bare fluffy glass fibers 100 are dip-coated in PbTe nanocrystal solution 102,
a. coated glass fibers 100 are then taken out, as illustrated by arrow 104, and dried;
   2) fibers 100 are dipped into 0.1M hydrazine aqueous solution 106 to get rid of excessive OA on the surface of fibers 100; and
   3) 99.8% anhydrous acetonitrile 108 is used to wash and to remove hydrazine and dry in nitrogen flow.

After dipping flexible substrates 100 into PbTe nanocrystal solution 102, coated substrate 100 is dried for approximately 15 seconds to approximately 60 seconds. After dipping coated substrate 100 into hydrazine aqueous solution 106, substrate 100 is not formally dried. Rather coated substrate 100 is quickly transferred to the acetonitrile solution, as illustrated by arrow 110. After dipping coated substrate 100 in acetonitrile solution 108 coated substrate 100 is dried for approximately 2 minutes to approximately 3 minutes.

This procedure is repeated, as illustrated by arrow 112 until a uniform film of thermoelectric material is coating flexible substrate 100. Approximately twenty cycles of procedure 300 is typically enough to achieve a uniform film. Uniform means that the coating thickness is the same everywhere. An objective measure of uniform is to measure and evaluate the thickness of the coating at several points on flexible substrate 100. Fewer cycles have not been tried. It is envisioned that several conditions in procedure 300 could be modified which would require less than twenty cycles to produce the uniform film. It is envisioned that modification of these conditions is within the scope of this disclosure.

Two hours of approximately 300° C. annealing is used to remove organic ligands and form a uniform layer on glass fibers 100 to produce lead telluride (PbTe) coated glass fibers 200 for further measurements. FIG. 1c depicts transmission electron microscopy images of PbTe nanocrystals after annealing.

The flexible substrates, such as bare fluffy glass fibers, were estimated to be approximately 1-2 inches long. This length is difficult to estimate because the flexible substrate is handled in fiber bundles, not individual fibers.

Regarding the dip-coating procedure, it is envisioned that the hydrazine aqueous solution could be replaced with a hydrazine/acetonitrile solution to achieve the same results.

Spark plasma sintering is used to make PbTe nanocrystals coated glass fibers into pellets for thermal conductivity measurement.

### RESULTS

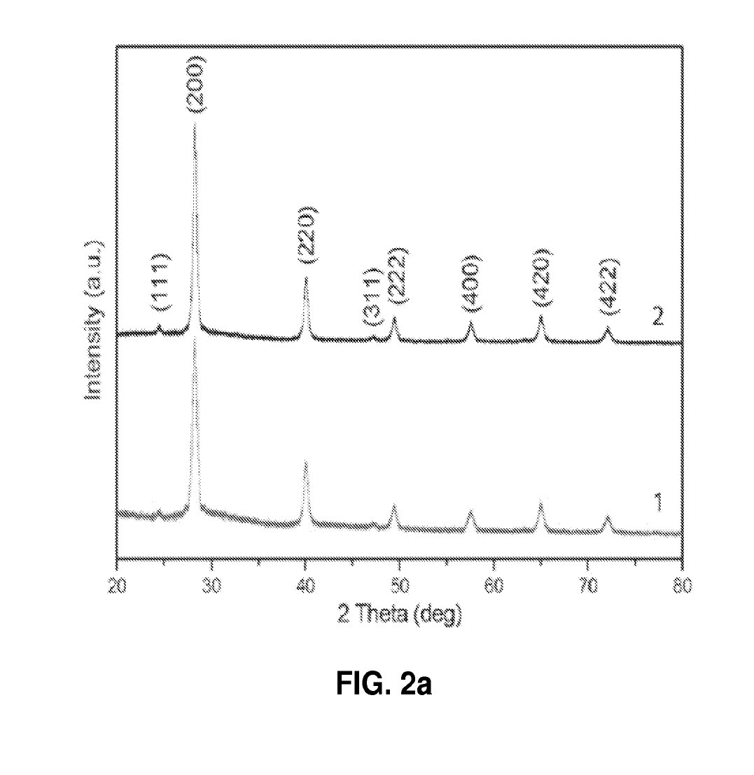

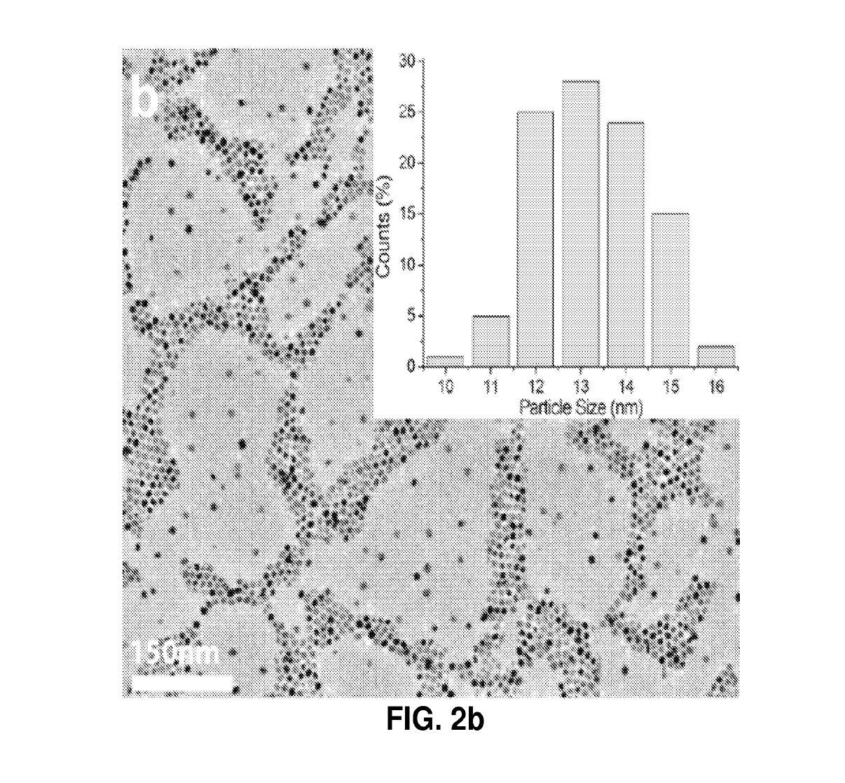

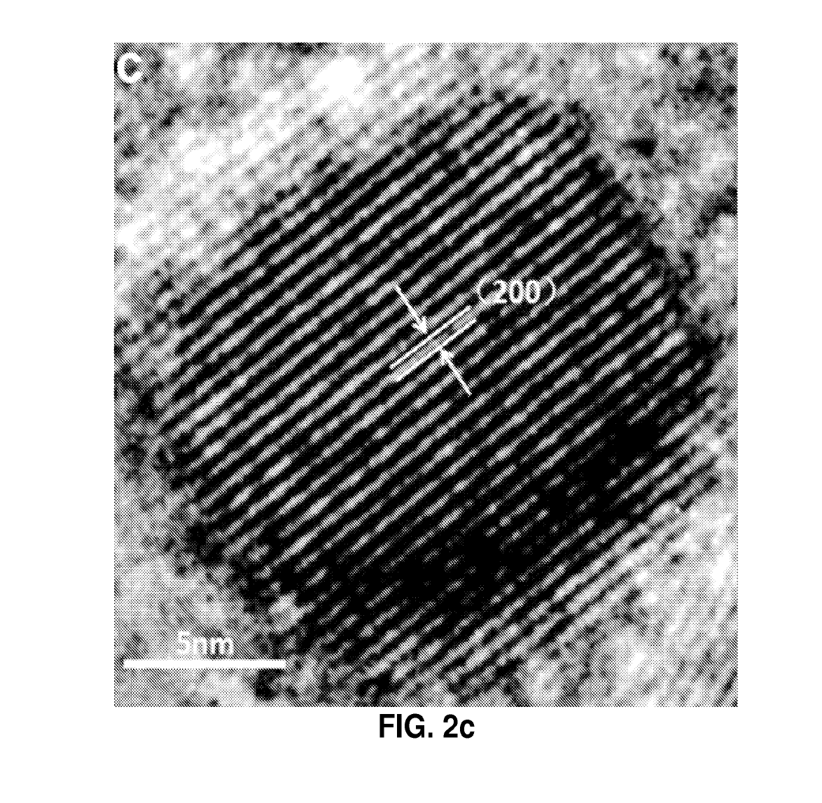

X-ray diffraction (XRD) studies (FIG. 2a) show the materials prepared according to the present disclosure are Altaite phase PbTe (JCPDS 38-1435), as correlated to a database maintained by the International Centre for Diffraction Data (ICDD) which was previously known as the Joint Committee on Powder Diffraction Standards (JCPDS). There is essentially no difference between the XRD patterns of samples before and after annealing, indicating that the PbTe nanocrystals remain the same as synthesized after the coating procedure. Low-resolution transmission electron microscopy (TEM) studies (FIG. 2b) show uniform nanocrystals with an average size (thickness) of about 13±3 nm (Inset, FIG. 2b). In high-resolution TEM image (FIG. 2c), it can clearly be seen that the distance between different crystal faces is 0.32 nm, indicating (200), which is the highest peak in XRD pattern for Altaite phase PbTe. At the same time, it shows that the PbTe nanocrystals are single-crystalline.

Scanning electron microscopy (SEM) studies (FIG. 1b) show the coated glass fibers have a uniform PbTe nanocrystal layer with the thickness of 300 nm.

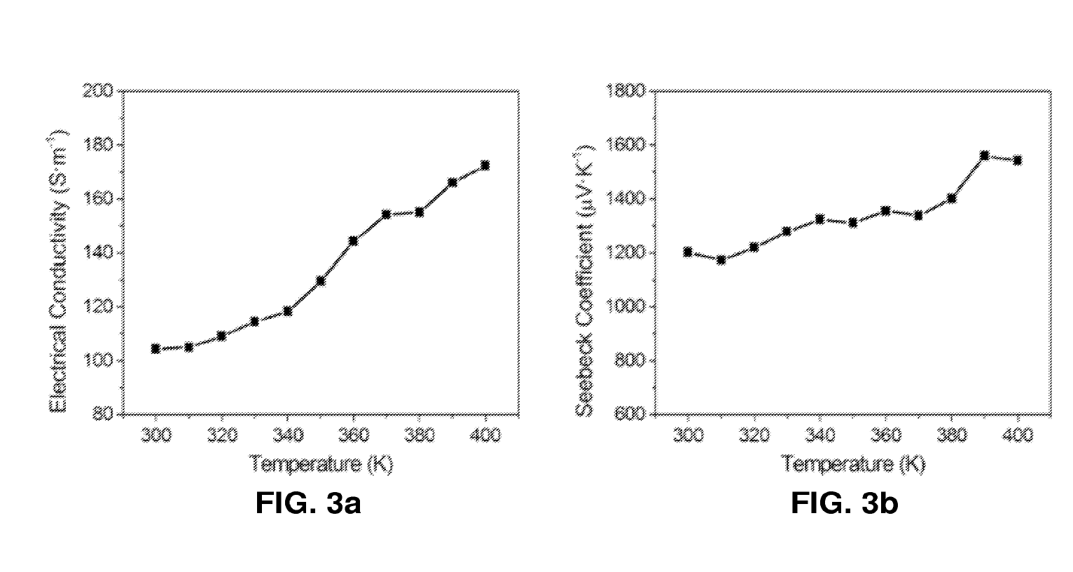

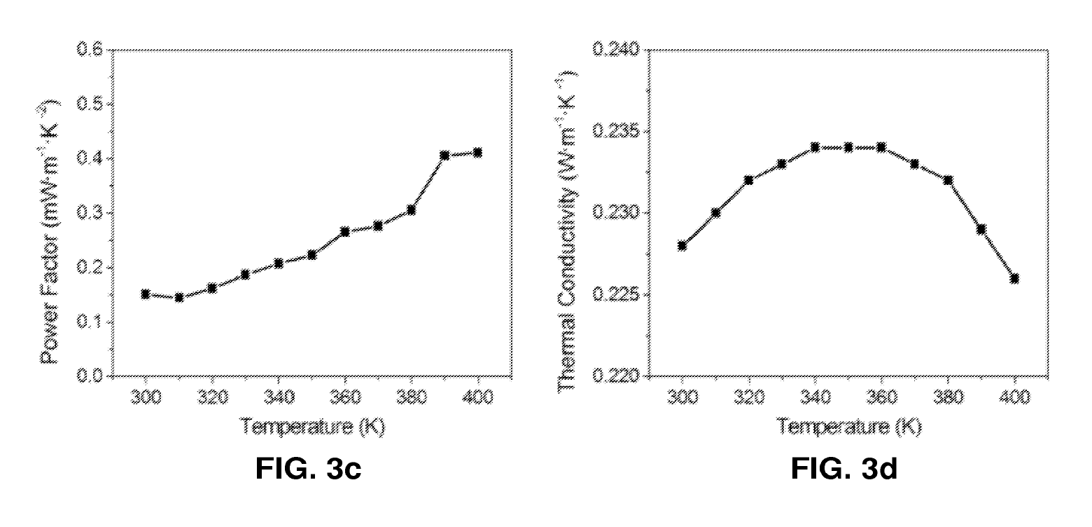

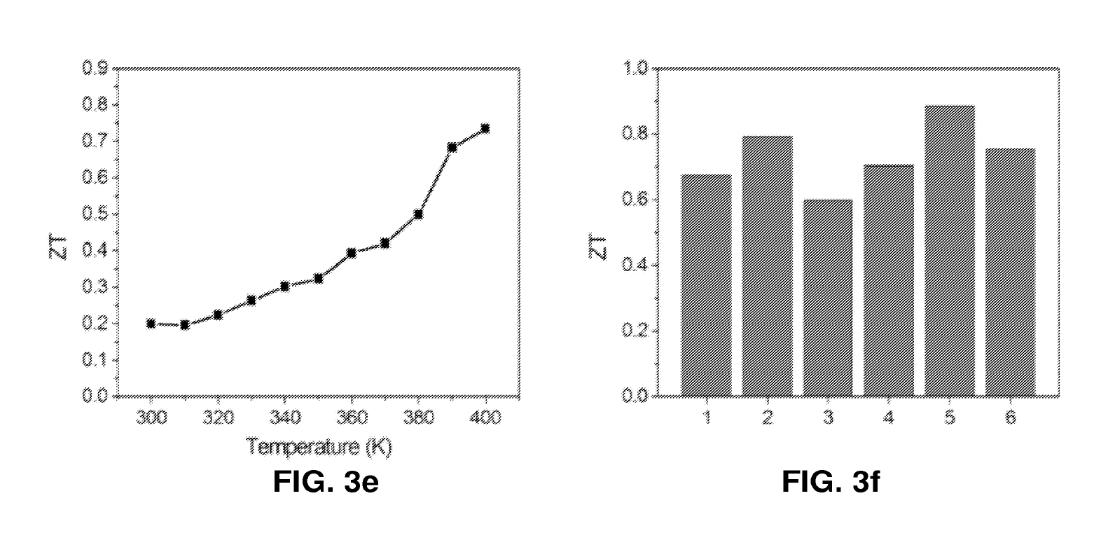

Electrical conductivity, Seebeck coefifcient and thermal conductivity of PbTe nanocrystals coated glass fibres have been investigated between 300 K and 400 K. The electrical conductivity (FIG. 3a) of the PbTe nanocrystals coated glass fibres increases from about 104.4 S·m⁻¹ at 300 K to about 172.4 S·m⁻¹ at 400 K. FIG. 3b depicts the temperature dependence of Seebeck coefficient of PbTe nanocrystals coated glass fibers. The positive Seebeck coefficient value indicates the p-type conduction. The Seebeck coefficient measurement shows an increasing trend from about 1201.71 μV·K⁻¹ at 300K to about 1542.4 μV·K⁻¹ at 400 K. The thermal conductivity of PbTe nanocrystals coated glass fibers is measured through thermal diffusivity and specific heat and then calculated via the equation:

K=αpCₚ

wherein α is thermal diffusivity, p is the density, Cp is the specific heat.

The thermal conductivity (FIG. 3d) at 300 K is measured to be about 0.228 W·m⁻¹·K⁻¹ and goes up to about 0.234 W·m⁻¹·K⁻¹ around 350 K, and then down to about 0.226 W·m⁻·K⁻¹. The calculated power factor for the PbTe nanocrystals coated glass fibers (FIG. 3c) increases from about 0.15 mW·m⁻¹·K⁻² to about 0.41 mW·m⁻¹·K⁻². The ZT for the PbTe nanocrystals coated glass fibers (FIG. 3e) increases from about 0.20 at 300K to about 0.73 at 400K. FIG. 3f depicts a histogram of highest ZT values obtained from different measurements.

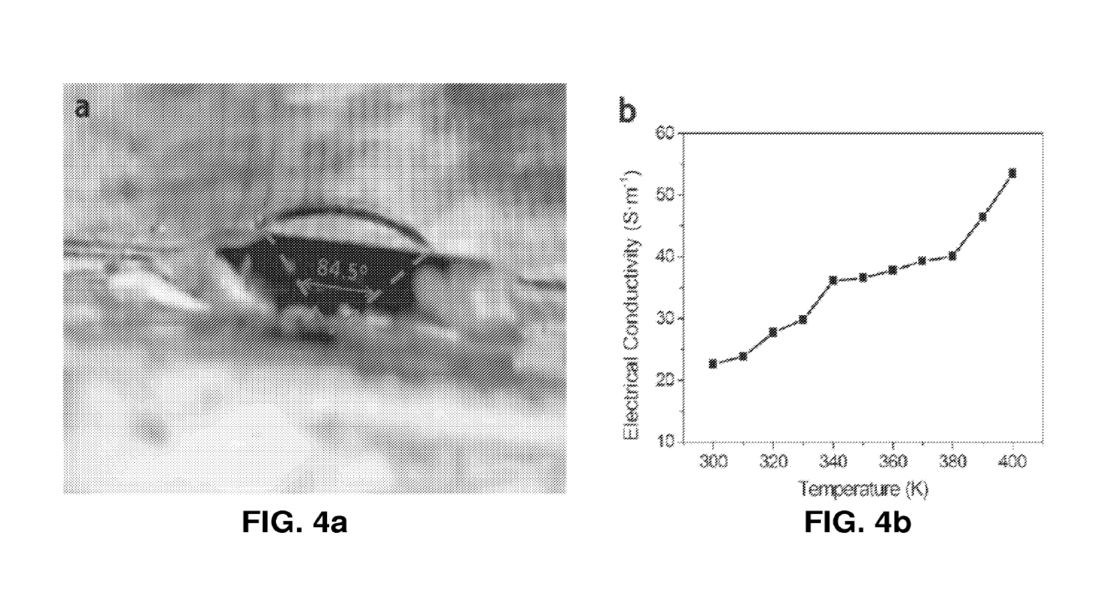

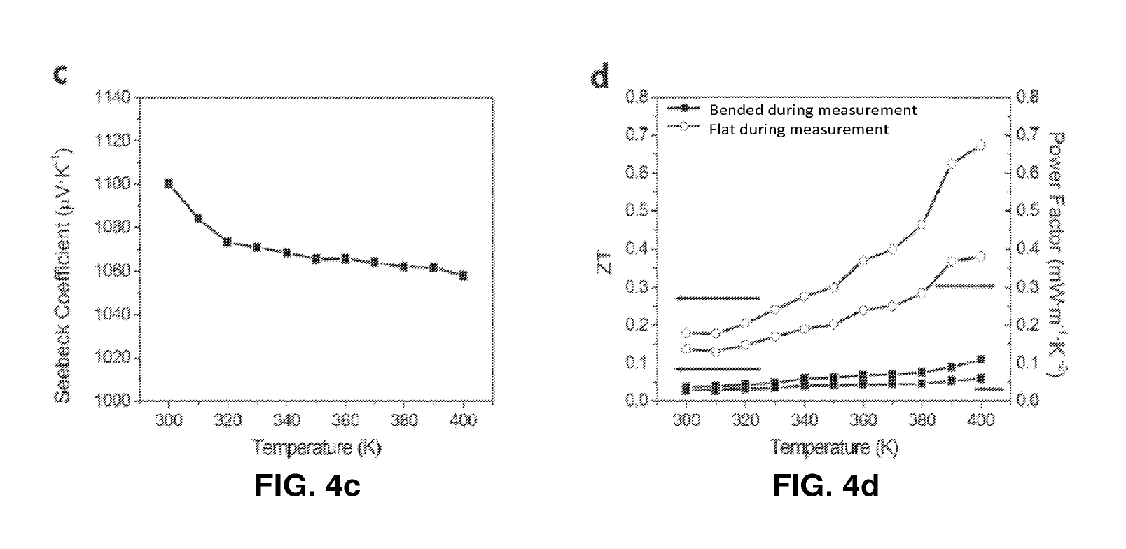

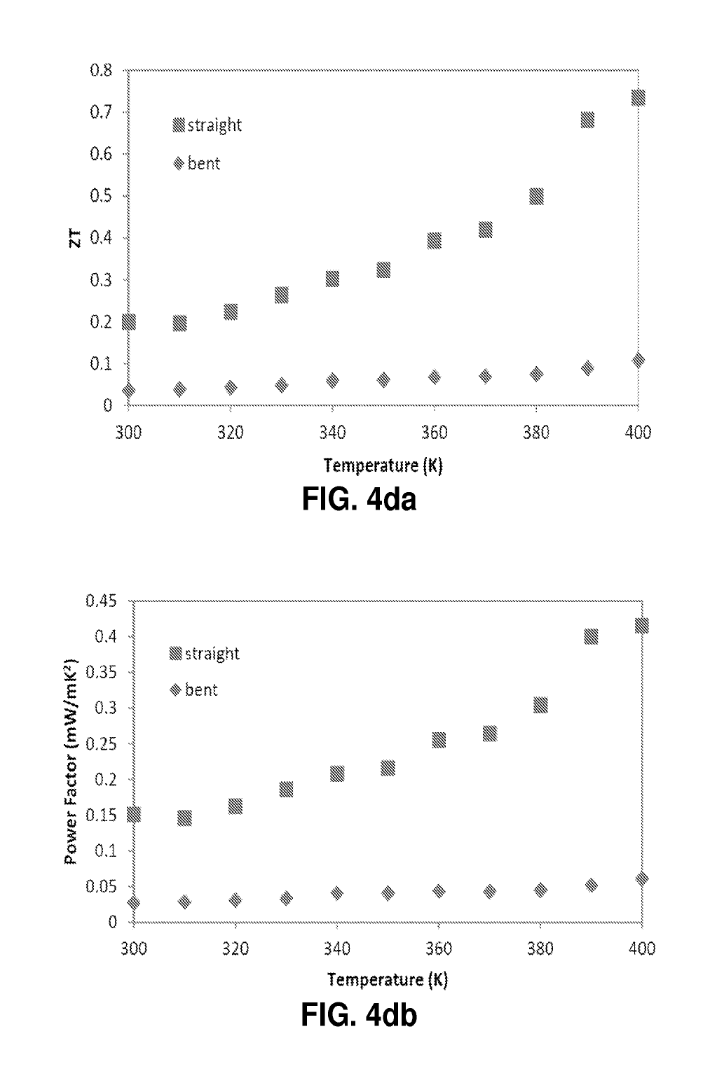

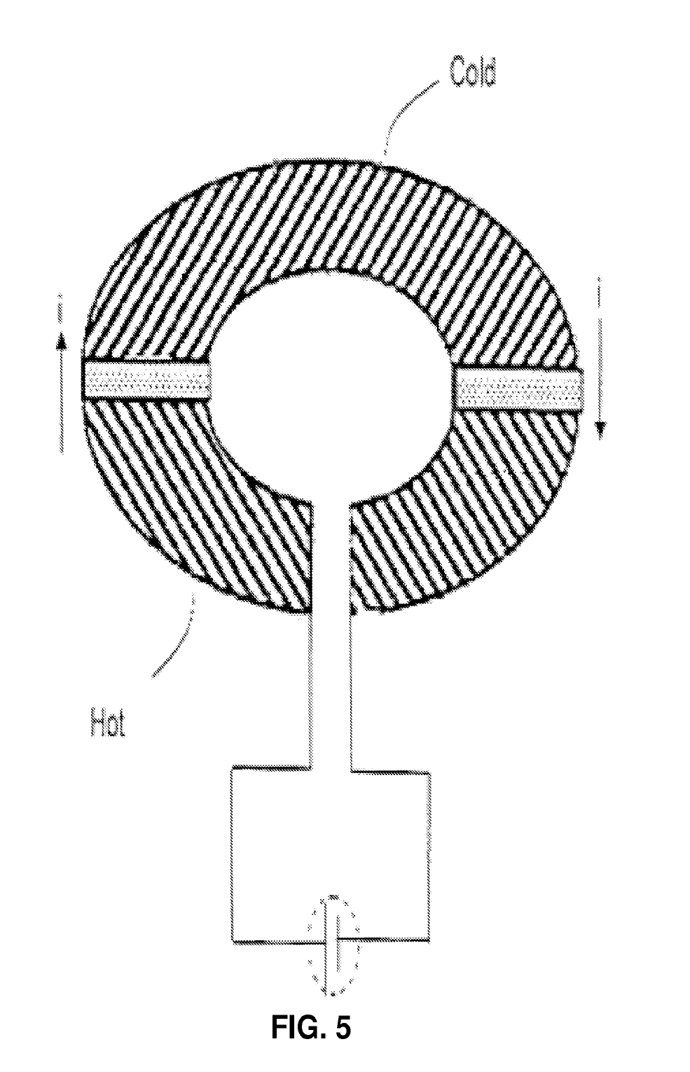

Additionally, thermoelectric properties of bended fibers were measured between 300K and 400K. The electrical conductivity (FIG. 4b) of bended fibers increases from about 22.7 S·m⁻¹ at 300 K to about 53.5 S·m⁻¹ at 400 K. FIG. 4c shows the temperature dependence of Seebeck coefficient of bended fibers. The positive Seebeck coefficient value indicates the p-type conduction. The Seebeck coefficient measurement shows a decreasing trend from 1100.2 μV·K⁻¹ at 300 K to 1058.0 μV·K⁻¹ at 400 K. The thermal conductivity of bended fibers is the same as before. The calculated power factor for bended fibers (FIG. 4d) increases from 0.027 mW·m⁻¹·K⁻² at 300 K to about 0.105 at 400 K. The ZT for bended fibers (FIG. 4d) increases from about 0.036 at 300 K to about 0.105 at 400 K. FIG. 4a depicts a curvature of 84.5° during all the thermoelectric measurements.

Those skilled in the art will recognize that numerous modifications can be made to the specific implementations described above. Therefore, the following claims are not to be limited to the specific embodiments illustrated and described above. The claims, as originally presented and as they may be amended, encompass variations, alternatives, modifications, improvements, equivalents, and substantial equivalents of the embodiments and teachings disclosed herein, including those that are presently unforeseen or unappreciated.

While this disclosure has been described as having an exemplary design, the present disclosure may be further modified within the spirit and scope of this disclosure. This application is therefore intended to cover any variations, uses, or adaptations of the disclosure using its general principles. Further, this application is intended to cover such departures from the present disclosure as come within known or customary practice in the art to which this disclosure pertains.

What is claimed is:

1. A thermoelectric structure, comprising:
a flexible substrate, and
nanocrystals coated over the flexible substrate.

2. The structure of claim 1 wherein nanocrystals include telluride.

3. The structure of claim 2 wherein nanocrystals include lead telluride.

4. The structure of claim 2 wherein nanocrystals include lead (II) telluride.

5. The structure of claim 1 wherein coating has a uniform average thickness of approximately 300 nm.

6. A method of coating lead telluride nanocrystals on a flexible substrate, the method comprising the steps of:
synthesizing lead telluride nanocrystals in solution, comprising the steps of:
degassing and drying a first solution of lead oxide, oleic acid and 1-octodecene at 140° C. for at least approximately one hour under an inert atmosphere,
contacting the first solution with a second solution of tri-n-octylphosphine and tellurium, wherein the second solution is prepared in a glovebox,
quenching the reaction by immersing the mixture in a water bath, and
contacting the reaction mixture with hexane;
coating lead telluride nanocrystals on a flexible substrate, comprising the steps of:
contacting flexible substrate to lead telluride nanocrystals,
drying nanocrystal coated flexible substrate,
contacting nanocrystal coated flexible substrate with hydrazine aqueous solution, and
contacting nanocrystal coated flexible substrate with acetonitrile;
repeating each coating step until nanocrystals form a uniform film on nanocrystal coated flexible substrate, and
annealing nanocrystal coated flexible substrate to form a uniform layer of nanocrystal on flexible substrate.

7. The method of claim 6 wherein the step of contacting flexible substrate to lead telluride nanocrystals includes dip-coating flexible substrate in lead telluride nanocrystal solution.

8. The method of claim 6 wherein the drying step includes where nanocrystal coated flexible substrate is dried within the range of approximately fifteen seconds and approximately sixty seconds.

9. The method of claim 6 wherein the step of contacting nanocrystal coated flexible substrate with acetonitrile also includes the step of drying substrate in nitrogen flow.

10. The method of claim 9 wherein the step of drying substrate in nitrogen flow includes where nanocrystal coated flexible substrate is dried within the range of approximately two minutes and approximately three minutes.

11. The method of claim 6 wherein the step of annealing includes where nanocrystal coated flexible substrate is annealed at approximately 300° C. for approximately two hours.

12. The method of claim 6, wherein the second solution includes a tri-n-octylphosphine and tellurium concentration of approximately 0.5 M.

13. The method of claim 12, wherein the second solution is diluted with approximately 90% 1-Octadecene.

14. The method of claim 6, wherein approximately 3 mL of approximately 0.5 M tri-n-octylphosphine and tellurium concentration is contacting the first solution.

15. The method of claim 6, further comprising the step of allowing the reaction to proceed for approximately 1 minute at approximately 250° C.

16. The method of claim 6, further comprising the step of washing the reaction mixture with a solvent pair.

17. The method of claim 16, wherein the solvent pair includes hexane and acetone.

18. The method of claim 16, wherein the step of washing is performed three times.
